(19) United States
(12) Patent Application Publication
(10) Pub. No.: US 2013/0344246 A1
(43) Pub. Date: Dec. 26, 2013

(54) Dual-Chamber Reactor for Chemical Vapor Deposition

(71) Applicant: Xuesong Li, Wappingers Falls, NY (US)

(72) Inventor: Xuesong Li, Wappingers Falls, NY (US)

(21) Appl. No.: 13/529,070

(22) Filed: Jun. 21, 2012

(51) Int. Cl. C23C 16/455

(52) U.S. Cl. 427/255.28; 118/724

(57) ABSTRACT

An apparatus for performing film deposition includes one or more processing tubes, a heat source, one or more reactant gas manifolds, and one or more exhaust gas manifolds. The one or more processing tubes define a first reaction space and a second reaction space that are not in gaseous communication. The heat source is translatable so as to direct energy into the first reaction space when the energy source is in a first position, and to direct energy into the second reaction space when the energy source is in a second position. The one or more reactant gas manifolds are operative to introduce a first reactant gas flow into the first reaction space, and to introduce a second reactant gas flow into the second reaction space. The one or more exhaust gas manifolds are operative to exhaust gases from the first reaction space and from the second reaction space.

### FIELD OF THE INVENTION

The present invention relates generally to apparatus and methods for chemical processing, and, more particularly, to reactors for chemical vapor deposition.

### BACKGROUND OF THE INVENTION

Chemical vapor deposition (CVD) is widely used in the semiconductor industry as well as other industries to form non-volatile solid-films on a substrate. In a typical CVD process, a given composition and flow of reactant gases are introduced into a reaction space where a substrate is located. There, the reactants undergo chemical reactions in the gas phase and/or with the substrate so as to form a film on the substrate. The reaction by-products are then exhausted from the reaction space.

Tube furnace CVD systems (horizontal or vertical) are commonly utilized for film deposition by CVD. In a typical tube furnace CVD system, a cylindrical quartz or alumina processing tube is utilized as the reaction chamber. The processing tube is surrounded by a heating furnace comprising resistively-heated heating elements (e.g., heating coils), which are utilized to heat the substrate located inside the processing tube. The chemical reactants are normally flowed into the processing tube from one end of the tube and the unreacted reactants and reaction by-products are exhausted from the opposing end of the processing tube.

Nevertheless, despite their widespread use, tube furnace CVD systems may suffer from several disadvantages. One of the disadvantages is the limitation for rapid thermal processing (RTP), which requires rapid heating and/or cooling rates. One way of utilizing a tube furnace CVD system for RTP is to utilize a long processing tube and a furnace that may slide along the length of the processing tube, although such a method is not admitted as prior art by its mention in this Background Section. A rapid heating process may be achieved by moving the preheated furnace to surround the substrate in the processing tube, and a rapid cooling process may be achieved by moving the furnace away from where the substrate is located in the processing tube. Nevertheless, when the film deposition process is done and the hot furnace is moved to a cold position, some of the molecules adsorbed on the wall of the processing tube at that position may be desorbed due to a rapid increase in temperature. These desorbed molecules may contaminate and/or damage the film deposited on the substrate. Another disadvantage of this method is that system throughput is substantially impacted by the time needed to cool, load, and unload substrates.

For the foregoing reasons, there is a need for CVD reactors that can achieve high heating and cooling rates with high throughput and without contaminating or damaging the product films.

### SUMMARY OF THE INVENTION

Embodiments of the present invention address the above-identified needs by providing new apparatus for film deposition by CVD, as well as methods for their use.

In accordance with an aspect of the invention, an apparatus for performing film deposition includes one or more processing tubes, a heat source, one or more reactant gas manifolds, and one or more exhaust gas manifolds. The one or more processing tubes define a first reaction space and a second reaction space. The second reaction space is not in gaseous communication with the first reaction space. At the same time, the heat source is translatable so as to direct energy into at least a portion of the first reaction space when the energy source is in a first position, and to direct energy into at least a portion of the second reaction space when the energy source is in a second position. The one or more reactant gas manifolds are operative to introduce a first reactant gas flow into the first reaction space, and to introduce a second reactant gas flow into the second reaction space. Lastly, the one or more exhaust gas manifolds are operative to exhaust gases from the first reaction space and from the second reaction space.

In accordance with another aspect of the invention, film is deposited utilizing a reactor. A first substrate is placed into a first reaction space while performing film deposition in a second reaction space that is not in gaseous communication with the first reaction space. A first reactant gas is then introduced into the first reaction space and a heat source is translated to a first position so as to direct energy into at least a portion of the first reaction space. Subsequently, a second substrate is placed into the second reaction space while performing film deposition in the first reaction space. With the second substrate in place, a second reactant gas flow is introduced into the second reaction space and the heat source is translated to a second position so as to direct energy into at least a portion of the second reaction space.

In accordance with even another aspect of the invention, a product of manufacture comprises a film deposited in an apparatus. The apparatus includes one or more processing tubes, a heat source, one or more reactant gas manifolds, and one or more exhaust gas manifolds. The one or more processing tubes define a first reaction space and a second reaction space. In so doing, the second reaction space is not in gaseous communication with the first reaction space. The heat source is translatable so as to direct energy into at least a portion of the first reaction space when the energy source is in a first position, and to direct energy into at least a portion of the second reaction space when the energy source is in a second position. The one or more reactant gas manifolds are operative to introduce a first reactant gas flow into the first reaction space, and to introduce a second reactant gas flow into the second reaction space. Lastly, the one or more exhaust gas manifolds are operative to exhaust gases from the first reaction space and from the second reaction space.

### BRIEF DESCRIPTION OF THE DRAWINGS

These and other features, aspects, and advantages of the present invention will become better understood with regard to the following description, appended claims, and accompanying drawings where:

FIG. 1 shows a side elevational view of at least a portion of a CVD reactor in accordance with an illustrative embodiment of the invention;

FIG. 2A shows an end elevational view of the processing tube in the FIG. 1 CVD reactor embodiment;

FIG. 2B shows a sectional view of the processing tube in the FIG. 1 CVD reactor embodiment;

FIG. 3A shows an end elevational view of one of the inner gas tubes in the FIG. 1 CVD reactor embodiment;

FIG. 3B shows a sectional view of one of the inner gas tubes in the FIG. 1 CVD reactor embodiment;

FIG. 4 shows a partial sectional view of one of the end adaptors in the FIG. 1 CVD reactor embodiment;

FIG. 5A shows a block diagram of a reactant gas manifold for use with the FIG. 1 CVD reactor embodiment in accordance with an illustrative embodiment of the invention;

FIG. 5B shows a block diagram of an illustrative exhaust gas manifold for use with the FIG. 1 CVD reactor embodiment in accordance with an illustrative embodiment of the invention;

FIGS. 6A and 6B show flow diagrams of a method for performing film deposition using the FIG. 1 CVD reactor embodiment in accordance with an illustrative embodiment of the invention;

FIG. 7 shows a sectional view of an alternative processing tube arrangement in accordance with an illustrative embodiment of the invention; and

FIGS. 8A-8C show side elevational views of three alternative inner gas delivery tube arrangements in accordance with illustrative embodiments of the invention.

### DETAILED DESCRIPTION OF THE INVENTION

The present invention will be described with reference to illustrative embodiments. For this reason, numerous modifications can be made to these embodiments and the results will still come within the scope of the invention. No limitations with respect to the specific embodiments described herein are intended or should be inferred.

The term “film deposition” as used herein is intended to encompass what is commonly called film deposition, film growth, and film synthesis. Thus, the term “film deposition” would comprise the forming of films that differ in composition and/or crystallinity from the respective substrates on which they are deposited, as well as the forming of films that substantially match the composition and crystallinity of the respective substrates on which they are deposited.

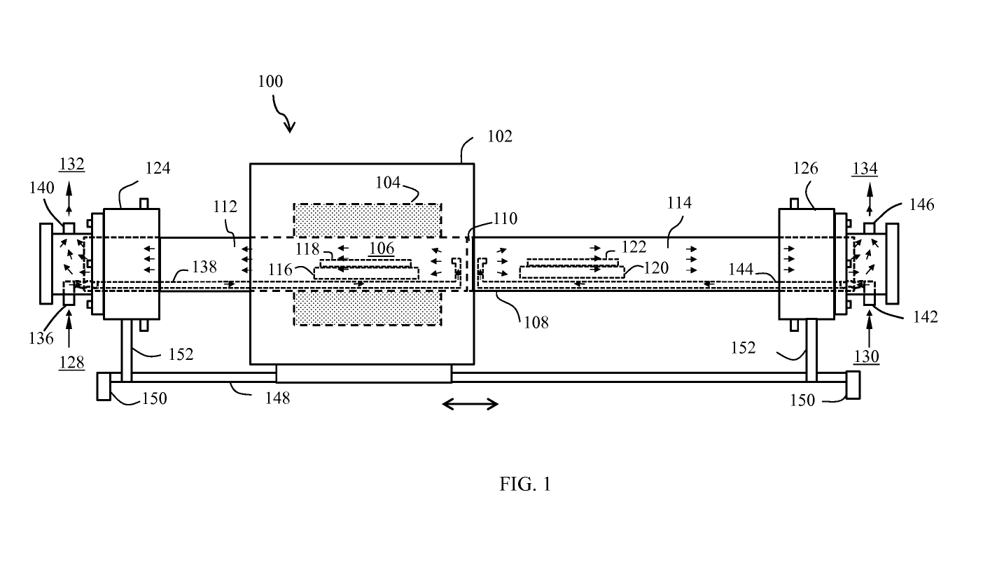

FIG. 1 shows a side elevational view of at least a portion of a CVD reactor 100 in accordance with an illustrative embodiment of the invention. The CVD reactor 100 includes a heat source 102 with heating elements 104 that define a hollow cylindrical heated space 106. A cylindrical processing tube 108 passes through this heated space 106.

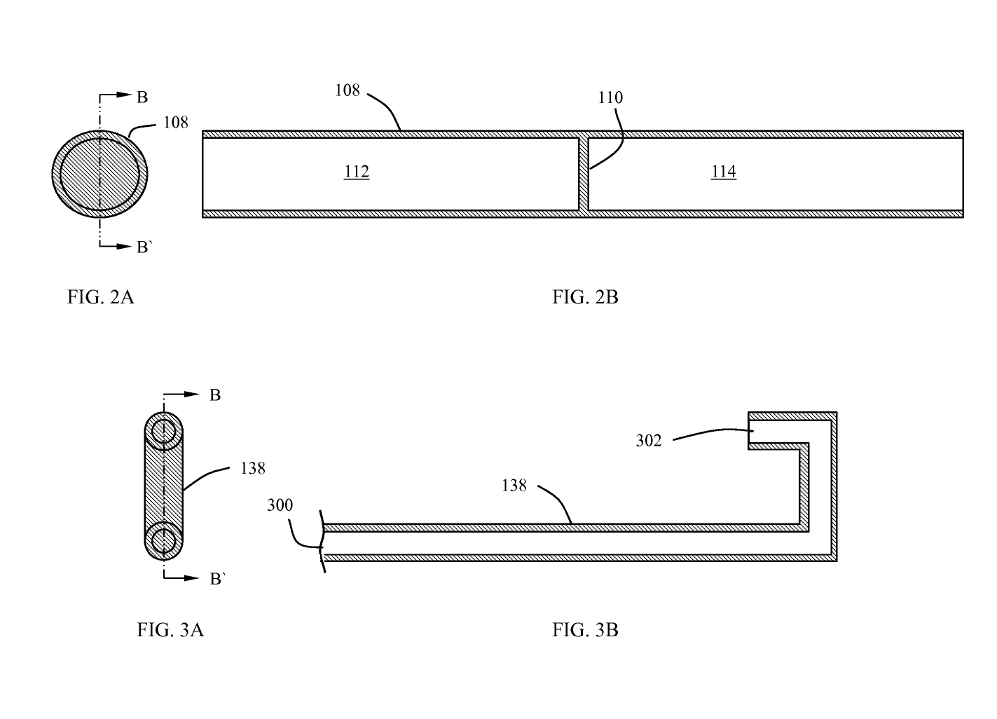

FIG. 2A shows an end elevational view of the processing tube 108, while FIG. 2B shows a sectional view of the processing tube 108 cut along the plane indicated in FIG. 2A. The processing tube 108 has two open ends. In the middle of the processing tube 108, a partition 110 acts to separate a left reaction space 112 from a right reaction space 114, thereby creating what could be called a “dual-chamber” CVD reactor. The partition 110 is gas tight, meaning that the left reaction space 112 is not in gaseous communication with the right reaction space 114. A left substrate support 116 and a left substrate 118 are disposed within the left reaction space 112. Likewise, a right substrate support 120 and a right substrate 122 are disposed within the right reaction space 114.

The introduction of reactant gas flows into the left and right reaction spaces 112, 114 and the exhausting of unused reactant gases and reaction byproducts from these reaction spaces 112, 114 are facilitated by use of a left end adaptor 124 and a right end adaptor 126, respectively, in conjunction with a left reactant gas manifold 128, a right reactant gas manifold 130, a left exhaust gas manifold 132, and a right exhaust gas manifold 134. For the left reaction space 112, the left reactant gas manifold 128 is made to introduce a reactant gas flow into the left end adaptor 124 through a left gas inlet port 136, where it is passed to a left inner gas tube 138 that is disposed within the left reaction space 112. After entering the left inner gas tube 138, the reactant gas flow is transported along substantially the entire length of the left reaction space 112 before being released into the left reaction space 112. FIG. 3A shows an end elevational view of the left inner gas tube 138, while FIG. 3B shows a sectional view of the left inner gas tube 138. A first opening 300 receives the reactant gas flow and a second opening 302 expels that reactant gas flow into the left reaction space 112. At the same time, gases in the left reaction space 112 are exhausted through a left gas exhaust port 140, also built into the left end adaptor 124, where the gases are swept into the left exhaust gas manifold 132. In so doing, a right-to-left pattern of gas flow over the left substrate 118 is established in the left reaction space 112, as indicated by the arrows in FIG. 1. In a similar manner, a left-to-right pattern of reactant gas flow over the right substrate 122 is established in the right reaction space 114 (also indicated by arrows in FIG. 1) utilizing the right reactant gas manifold 130, the right exhaust gas manifold 134, a right input port 142, a right inner gas tube 144, and a right gas exhaust port 146.

Still referring to FIG. 1, the heat source 102 is slidably supported by two parallel rails 148 (only one of which is visible because of the angle of the view in the figure). These two parallel rails 148, in turn, are supported by two rail supports 150 that are, for example, fixed to the ground (not explicitly shown). The heat source 102 is thereby operative to be translated along the longitudinal axis of the processing tube 108. Notably, the left and right end adaptors 124, 126 are also slidably supported by the rails 148 via adaptor supports 152. These adaptor supports 152 may also be translated along the rail, giving the CVD reactor 100 the ability to change the distance between left and right end adaptors 124, 126 and thereby accommodate processing tubes of differing lengths. At the same time, the adaptor supports 152 themselves may be adjusted in height so that the CVD reactor 100 may accommodate processing tubes of differing diameters. In order to facilitate these height changes, the adaptor supports 152 may each comprise a respective set of telescopically coupled tubes that may be fixed at different lengths of expansion by aligned holes and pins, pneumatic actuation, hydraulic actuation, etc. (not explicitly shown).

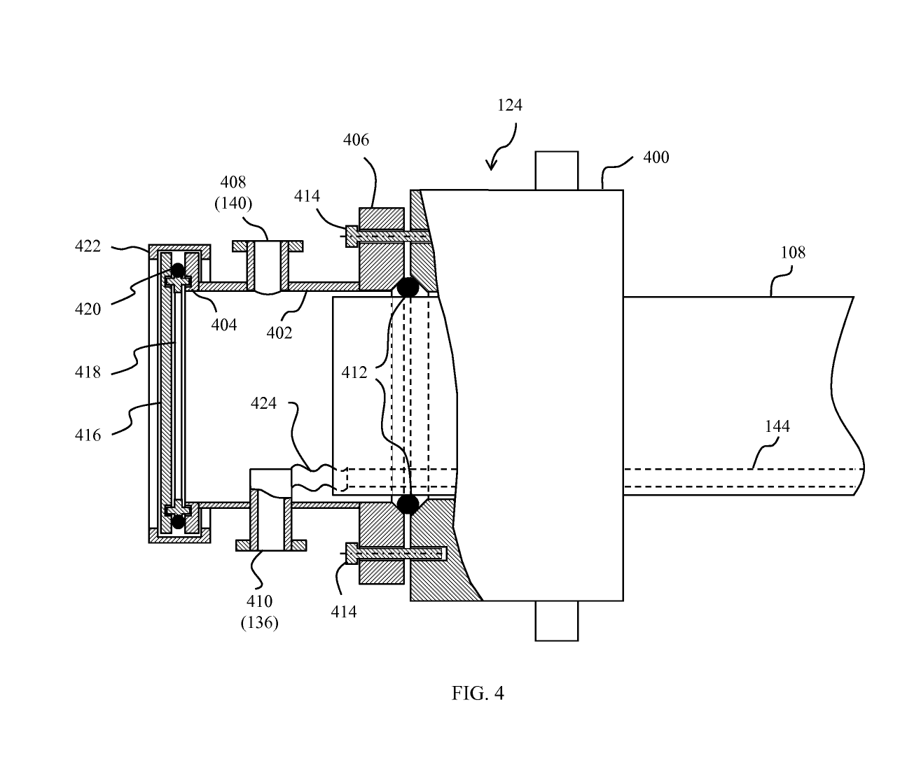

Additional details of the left end adaptor 124 are shown in the partial sectional view in FIG. 4. The right end adaptor 126 is substantially similar and is therefore not detailed herein for economy of description. The left end adaptor 124 comprises a water cooling flange 400 and a cross reducer 402 with a left flange 404, a right flange 406, an upper flange 408, and a lower flange 410. The lower flange 410 serves as part of the left gas inlet port 136, while the upper flange 408 serves as part of the left gas exhaust port 140. In order to couple the processing tube 108 to the left end adaptor 124, the left end of the processing tube 108 passes through the water cooling flange 400 and through the right flange 406 of the cross reducer 402, but does not block the left gas inlet port 136 and the left gas exhaust port 140. A right o-ring 412 is placed in between the water cooling flange 400 and the right flange 406. Bolts 414 are then utilized to firmly attach the cross reducer 402 to the water cooling flange 400. In so doing, angles on the water cooling flange 400 and the right flange 406 act to press the right o-ring 412 against the outer wall of the processing tube 108 so as to create a gas-tight seal between the left end adapter 124 and the processing tube 108. The left flange 404 of the cross reducer 402 is covered by a blank flange 416. A center ring 418 and a left o-ring 420 are disposed between the blank flange 416 and the cross reducer 402 to also seal the gap therebetween. A clamp 422 is utilized to fix the blank flange 416 to the cross reducer 402. By tightening and untightening the clamp 422, the blank flange 416 can be readily fixed to or removed from the cross reducer 402, behaving as a convenient gate for loading and unloading the left substrate 118. A flexible tube 424 is utilized to connect the left gas inlet port 136 with the left inner gas tube 138. The flexibility of this connection also facilitates the use of processing tubes of different diameters.

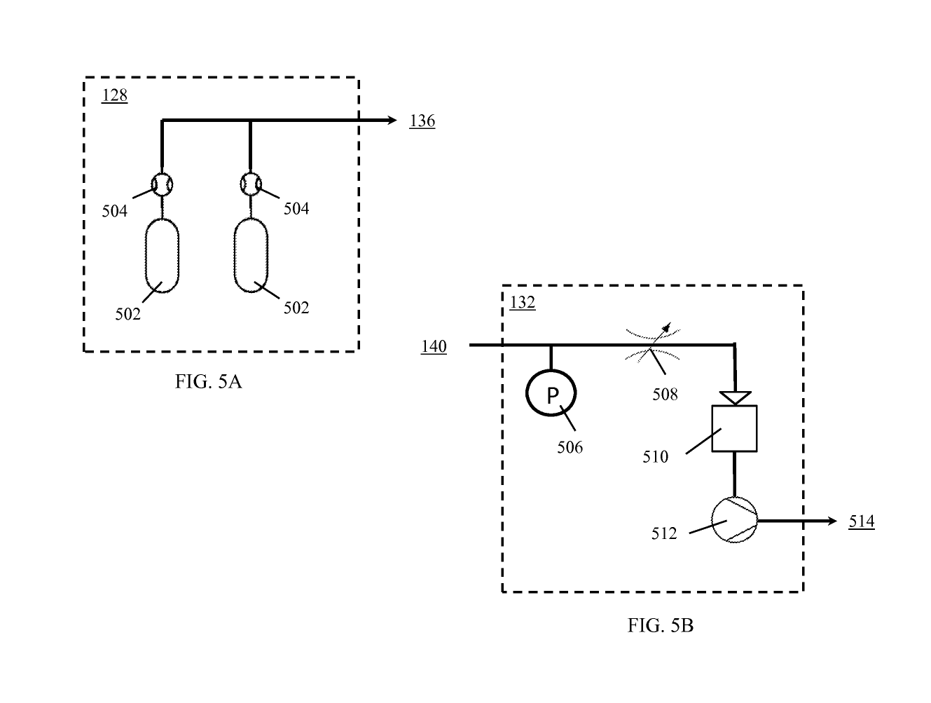

As indicated above, the introduction of reactant gas flows into the left and right reaction spaces 112, 114 and the exhausting of unused reactant gases and reaction byproducts from these reaction spaces 112, 114 in the illustrative CVD reactor 100 are facilitated by the use of two separate reactant gas manifolds 128, 130 and two separate exhaust gas manifolds 132, 134. FIG. 5A shows a schematic diagram of a representative one of the two reactant gas manifolds 128, 130, in this case, the left reactant gas manifold 128. In the present illustrative embodiment, the left reactant gas manifold 128 comprises two process gas sources 502, although this particular number of process gas sources is largely arbitrary and a gas manifold with a fewer or a greater number of process gas sources would still fall within the scope of the invention. Each process gas source 502 is in gaseous communication with a respective mass flow controller 504 that acts to regulate the flow rate of the gas coming from that process gas source 502 into the left gas inlet port 136.

FIG. 5B, in turn, shows a schematic diagram of a representative one of the two exhaust gas manifolds 132, 134, in this particular case, the left exhaust gas manifold 132. Here, any gases leaving the left reaction space 112 pass through a pressure sensor 506 (e.g., pressure controller) before entering a throttle valve 508. The pressure sensor 506 measures the pressure and, via a conventional electronic feedback mechanism, controls the opening of the throttle valve 508 to regulate a preset pressure in the left reaction space 112. Once past the throttle valve 508, the gases then pass through a trap 510 (e.g., liquid nitrogen trap) and then are pumped by a rotary mechanical pump 512 before being sent to an exhaust 514. The rotary mechanical pump 512 is operative to reduce respective pressures in the left reaction space 112 below atmospheric pressure. A chemical scrubber (not explicitly shown) may be provided if deemed necessary.

Utilizing separate reactant gas manifolds 128, 130 and separate exhaust gas manifolds 132, 134 for the left and right reaction spaces 112, 114 has the advantage of providing independent process control for each of these reaction spaces 112, 114. That said, it is recognized that several of the components shown in FIGS. 5A and 5B may be shared among the reactant gas manifolds 128, 130 and the exhaust gas manifolds 132, 134, as the case may be, to aid in economy of design. For example, it is contemplated that the reactant gas manifolds 128, 130 might share common process gas sources, or that the exhaust gas manifolds 132, 134 may share a common rotary mechanical pump. In fact, if independent process control for each of the reaction spaces 112, 114 is not required, it may not be necessary to partition the reactant gas manifolds 128, 130 and the exhaust gas manifolds 132, 134 at all. Instead, a universal reactant gas manifold and a universal exhaust gas manifold may be sufficient to service both reaction spaces 112, 114.

The heating elements 104 of the heat source 102 may comprise one or more resistively-heated wire elements that are coiled around (i.e., encircle) the hollow cylindrical heated space 106 and are supported by an insulating matrix (e.g., refractory metal oxide or fibrous refractory metal oxide). The heat source 102 thereby forms what is sometimes called a “CVD tube furnace.” If desired, several distinct coils may be arranged along the longitudinal axis of the heated space 106 to create separately-controllable heating zones. Such zones are sometimes useful to, for example, address reactant depletion effects. For temperature regulation, signals from thermocouples in the reaction spaces 112, 114 (not explicitly shown) may be fed back to a power supply (e.g., programmable power supply) for the heat source 102 so as to maintain a predetermined temperature set point. The length of the heated space 106 may, for example, be between about 100 centimeters (cm) to about 120 cm while the diameter may be about 8 cm, although these dimensions are purely illustrative. As will be appreciated by one skilled in the art given the teachings herein, the heat source 102 can be scaled to any size required for any given application.

The various elements of the CVD reactor 100 may be formed from largely conventional materials. The processing tube 108 and the inner gas tubes 138, 144 may, for example, comprise a material such as, but not limited to, quartz or alumina. The substrate supports 116, 120 may comprise a material such as, but not limited to, quartz, alumina, or a metal. The end adaptors 124, 126, the two parallel rails 148, the two rail supports 150, and the two adaptor supports 152 may comprise a metal such as, but not limited to, aluminum or stainless steel. Rubber components such as the o-rings 412, 420 may be made of a high temperature elastomer such as, for example, a perfluoroelastomer. The mass flow controllers 504, throttle valves 508, pumps 512, and so forth forming the reactant gas manifolds 128, 130 and the exhaust gas manifolds 132, 134 may be sourced from commercial vendors (e.g., MKS Instruments, Inc. (Andover, Mass., USA)).

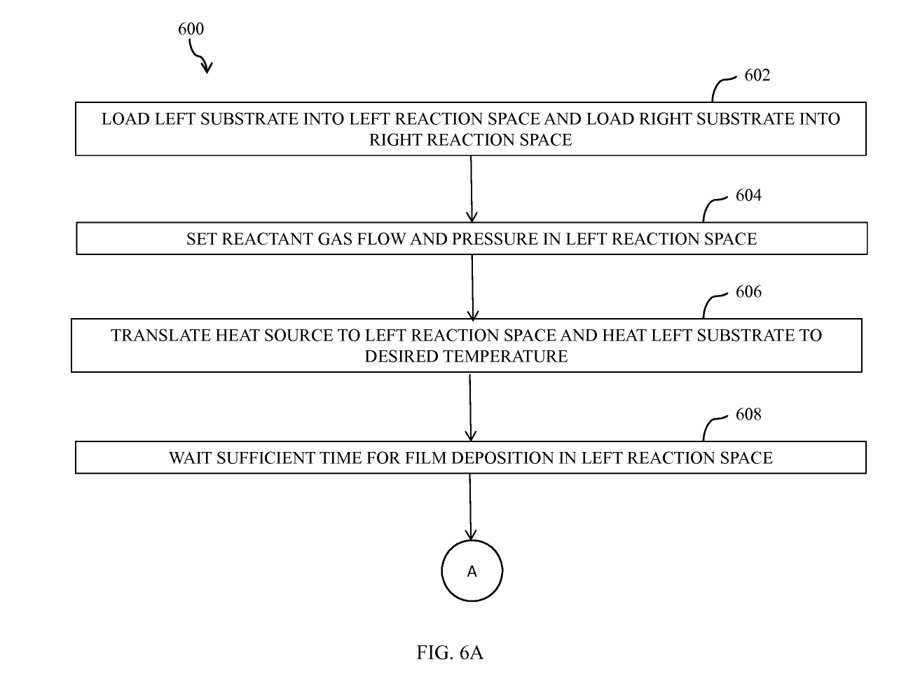

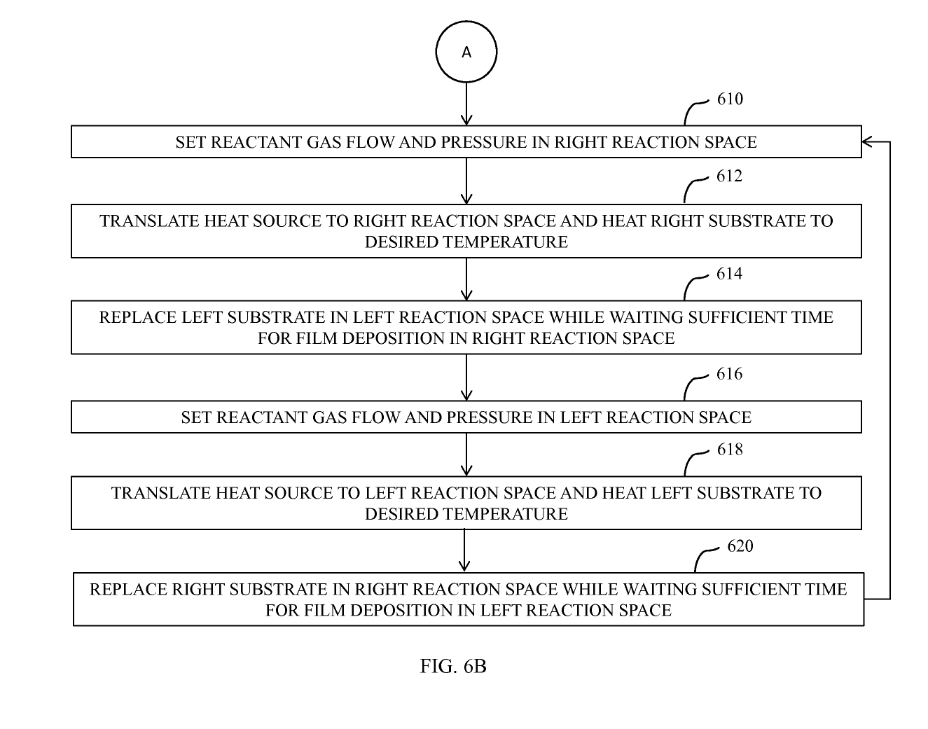

FIGS. 6A and 6B collectively show a flow diagram of a method 600 for performing film deposition using the CVD reactor 100, in accordance with an illustrative embodiment of the invention

In step 602 of FIG. 6A, the left substrate 118 is loaded into the left reaction space 112, and the right substrate 122 is loaded into the right reaction space 114. Subsequently, in step 604, the left reactant gas manifold 128 and the left exhaust gas manifold 132 are utilized to create the desired reactant gas flow rates and pressure in the left reaction space 112. At that point, in step 606, the heat source 102 is translated such that the portion of the left reaction space 112 that includes the left substrate 118 falls within the heated space 106 of the heat source 102. The left substrate 118 is thereby heated to the desired reaction temperature. In step 608, the just-configured reaction conditions are maintained in the left reaction space 112 for a time sufficient to allow the desired film deposition to occur on the left substrate 118.

Now referring to FIG. 6B, the method 600 continues at step 610, wherein the right reactant gas manifold 130 and the right exhaust gas manifold 134 are utilized to create the desired reactant gas flow rates and pressure in the right reaction space 114. The heat source 102, in step 612, is then translated such that the portion of the right reaction space 114 that includes the right substrate 122 falls within the heated space 106 of the heat source 102, thereby allowing the right substrate 122 to be heated to the desired reaction temperature. In step 614, the just-configured reaction conditions are again maintained in the right reaction space 114 for a time sufficient to allow the desired film deposition to occur on the right substrate 122. However, rather than simply standing idle while allowing the processing to continue, the left substrate 118 in the left reaction space 112 is, concurrently with the film deposition in the right reaction space 114, given sufficient time to cool down and then replaced by another (e.g., bare) left substrate 118. In so doing, the step 614 comprises both film deposition on one substrate (in this case, the right substrate 122 in the right reaction space 114) as well as the concurrent cooling and replacement of the other substrate (in this, case, the left substrate 118 in the left reaction space 112).

Such a pattern of concurrently processing and loading/unloading substrates 118 continues in steps 616-620. When step 614 is finished, the method 600 progresses to step 616. In step 616, the reactant flow rates and pressure are again established in the left reaction space 112 in a manner similar to step 604. In step 618, the heat source 102 is again translated over the left substrate 118 in a manner similar to step 606. Lastly, in step 620, the film deposition is allowed to occur in the left reaction space 112 while the right substrate 122 is allowed to cool and is replaced in the right reaction space 114. The method 600 then returns to step 610 and the steps 610-620 are caused to continue for as long as desired.

As indicated above, in the illustrative CVD reactor 100, the left reactant gas manifold 128 and the left exhaust gas manifold 132 service the left reaction space 112, while the right reactant gas manifold 130 and the right exhaust gas manifold 134 service the right reaction space 114. Accordingly film deposition processes with very different processing parameters may be conducted in each reaction space 112, 114, even when performing the processing in the manner set forth above with reference to FIGS. 6A and 6B.

Apparatus in accordance with aspects of the invention, such as the CVD reactor 100, may be operated manually, using automation, or by some combination thereof. It is contemplated, for example, that the loading and unloading of substrates 118, 122 into the reaction spaces 112, 114 could be accomplished by the use of robotics if so desired. Moreover, the translation of the heat source 102 may be accomplished by one or more electric motors or other forms of motive force. Such automation as this is widely used in, for example, the semiconductor arts when manufacturing integrated circuits. Accordingly, once aspects of the invention are understood from the teachings presented herein, such automation will be familiar to one skilled in the art and need not be detailed in this document. Such automation is also described in a number of readily available publications including, as just one example, K. Mathia, Robotics for Electronics Manufacturing: Principles and Applications in Cleanroom Automation, Cambridge University Press, 2010, which is hereby incorporated by reference herein.

Embodiments in accordance with aspects of the invention provide a number of advantages over conventional single-chamber tube CVD reactors. By providing a processing tube 108 with two independent reaction spaces 112, 114 that may be separately heated by a single heat source 102, for example, the illustrative CVD reactor 100 and, more generally, an apparatus in accordance with aspects of the invention, provide a greater throughput than can be achieved by conventional CVD reactors. More precisely, by utilizing a CVD reactor in accordance with aspects of the invention and running a film deposition process in one reaction space while concurrently cooling down the substrate and replacing it in the other reaction space, substantially less time is spent while the CVD reactor is not actively performing film deposition. What is more, a CVD reactor in accordance with aspects of the invention may avoid film contamination and damage issues associated with moving a heat source to a cold region of the same reaction space in which film deposition has just occurred, as may happen in single-reaction-space RTP tube CVD reactors (see Background). Lastly, CVD reactors in accordance with aspects of the invention do not create a physical footprint that is substantially larger than a conventional single-chamber tube CVD reactor, nor do they consume a substantially greater amount of energy per run.

It should again be emphasized that the above-described embodiments of the invention are intended to be illustrative only. Other embodiments can use different types and arrangements of elements for implementing the described functionality. These numerous alternative embodiments within the scope of the appended claims will be apparent to one skilled in the art.

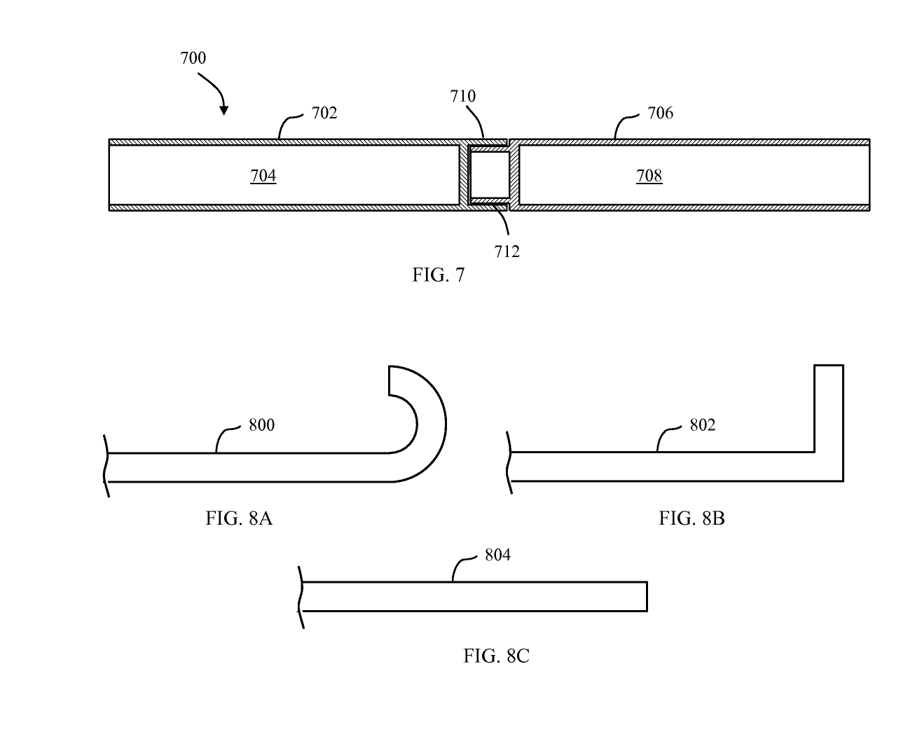

As just one example, while the illustrative CVD reactor 100 utilizes a single processing tube 108 with a partition 110 to define the left and right reaction spaces 112, 114, alternative embodiments in accordance with aspects of the invention can also utilize two separate processing tubes. FIG. 7 shows a sectional view of at least a portion of an alternative processing tube arrangement 700 in accordance with an illustrative embodiment of the invention. In this alternative embodiment, a left processing tube 702 defines a left reaction space 704, while a distinct right processing tube 706 defines a right reaction space 708. As indicated in the figure, the left processing tube 702 includes a female fitting 710 that overlaps a male fitting 712 included in the right processing tube 706. The two processing tubes 702, 706 are thereby arranged in line so as to facilitate the linear translation of a heat source like the heat source 102. In fact, the two processing tubes 702, 706 may, with little further modification, replace the single processing tube 108 in the CVD reactor 100.

As just another example, FIGS. 8A-8C show side elevational views of three alternative inner gas delivery tube arrangements in accordance with illustrative embodiments of the invention that may replace the left and right inner gas tubes 138, 144 in the CVD reactor 100. In contrast to the inner gas tubes 138, 144 shown in FIGS. 1 and 3B, an inner gas tube 800 shown in FIG. 8A has a curved end, while an inner gas tube 802 shown in FIG. 8B has an “L” shape. An alternative inner gas tube 806 shown in FIG. 8C is simply a straight tube without a bend or curve.

While the heat source 102 in the illustrative CVD reactor 100 utilizes resistively-heated heating elements 104, alternative embodiments in accordance with aspects of the invention may utilize several alternative sources of heat energy. These alternative sources include, but are not limited to, radiant heating with high intensity radiation lamps and electric induction heating. These heating options and other suitable options are described in a number of readily available publications, including A. C. Jones, Chemical Vapour Deposition: Precursors, Processes and Applications, Royal Society of Chemistry, 2009, which is hereby incorporated by reference herein. To utilize high-intensity radiation lamps in the CVD reactor 100, the heat source 102 may be fitted with a multiplicity of radiation lamps (e.g., tungsten filament lamps) driven by a voltage/current regulator. Ideally, the radiation lamps will produce a light spectrum that effectively heats the substrates 118, 122 and/or the substrate supports 116, 120 by radiant heating while being transmitted through the walls of the processing tube 108 with little absorption. Reflectors may be incorporated into the heat source 102 to help provide uniform illumination by the radiation lamps. Alternatively, if electric induction heating is desired, the heat source 102 may be configured with one or more electric coils surrounding the heated space 106 and driven by a radio frequency (rf) generator. The electric coils may be configured as tubes capable of circulating a cooling liquid in order to facilitate their cooling. A strong magnetic field formed in the heated space 106 may thereby induce induction heating in any electrically conductive elements disposed in the heated space (e.g., substrates 118, 120 and/or substrate supports 116, 120). Thermocouples and/or pyrometers may be used to feed back signals indicative of temperature to the voltage/current regulator or rf generator, as appropriate, to again maintain a predetermined temperature set point.

The features disclosed herein may be replaced by alternative features serving the same, equivalent, or similar purposes, unless expressly stated otherwise. Thus, unless expressly stated otherwise, each feature disclosed is one example only of a generic series of equivalent or similar features.

Any element in a claim that does not explicitly state “means for” performing a specified function or “step for” performing a specified function is not to be interpreted as a “means for” or “step for” clause as specified in 35 U.S.C. §112, ¶6. In particular, the use of “steps of” in the claims herein is not intended to invoke the provisions of 35 U.S.C. §112, ¶6.

What is claimed is:

1. An apparatus for performing film deposition, the apparatus comprising:
one or more processing tubes, the one or more processing tubes defining a first reaction space and a second reaction space, the second reaction space not in gaseous communication with the first reaction space;
a heat source, the heat source being translatable so as to direct energy into at least a portion of the first reaction space when the energy source is in a first position, and to direct energy into at least a portion of the second reaction space when the energy source is in a second position;
one or more reactant gas manifolds, the one or more reactant gas manifolds operative to introduce a first reactant gas flow into the first reaction space, and to introduce a second reactant gas flow into the second reaction space; and
one or more exhaust gas manifolds, the one or more exhaust gas manifolds operative to exhaust gases from the first reaction space and from the second reaction space.

2. The apparatus of claim 1, wherein the apparatus is operative to allow a substrate in the first reaction space to be replaced while the apparatus is performing film deposition in the second reaction space, and to allow a substrate in the second reaction space to be replaced while the apparatus is performing film deposition in the first reaction space.

3. The apparatus of claim 1, wherein the heat source comprises a resistively-heated heating element.

4. The apparatus of claim 3, wherein the resistively-heated heating element defines a coil adapted to encircle the at least a portion of the first reaction space when the heat source is in the first position, and to encircle the at least a portion of the second reaction space when the heat source is in the second position.

5. The apparatus of claim 1, wherein the heat source comprises a heating lamp.

6. The apparatus of claim 1, wherein the heat source comprises an electrical coil operative to direct a magnetic field into the at least a portion of the first reaction space when the heat source is in the first position, and to direct the magnetic field into the at least a portion of the second reaction space when the heat source is in the second position.

7. The apparatus of claim 1, wherein the heat source comprises a plurality of separately controllable zones.

8. The apparatus of claim 1, wherein the heat source is supported by one or more rails upon which the heat source may be translated.

9. The apparatus of claim 1, wherein the one or more processing tubes consist of a single processing tube with a partition that separates the first reaction space from the second reaction space.

10. The apparatus of claim 1, wherein the one or more processing tubes consist of a first processing tube and a second processing tube, the second processing tube being distinct from the first processing tube and arranged in line therewith.

11. The apparatus of claim 1, wherein the one or more processing tubes comprise at least one of quartz and alumina.

12. The apparatus of claim 1, wherein the one or more reactant gas manifolds are operative to cause the first reactant gas flow and the second reactant gas flow to have substantially different compositions.

13. The apparatus of claim 1, wherein the one or more exhaust gas manifolds are operative to determine a substantially different respective pressure for the first reaction space and the second reaction space.

14. The apparatus of claim 1, wherein the one or more exhaust gas manifolds are operative to reduce respective pressures in the first reaction space and the second reaction space below atmospheric pressure.

15. The apparatus of claim 1, further comprising a first inner gas line, the first inner gas line at least partially disposed within the first reaction space and adapted to receive the first reactant gas flow and to transport the first reactant gas flow along a length of the first reaction space before releasing the first reactant gas flow into the first reaction space.

16. The apparatus of claim 15, further comprising a second inner gas line, the second inner gas line at least partially disposed within the second reaction space and adapted to receive the second reactant gas flow and to transport the second reactant gas flow along a length of the second reaction space before releasing the second reactant gas flow into the second reaction space.

17. The apparatus of claim 1, further comprising a first end adaptor, the first end adaptor sealably coupled to one of the one or more processing tubes and comprising:
a first loading port, the first loading port adapted to allow a first substrate to be loaded into the first reaction space;
a first gas input port, the first gas input port in gaseous communication with one of the one or more reactant gas manifolds and the first reaction space; and
a first gas exhaust port, the first gas exhaust port in gaseous communication with one of the one or more exhaust gas manifolds and the first reaction space.

18. The apparatus of claim 17, wherein the first end adaptor is supported by one or more rails upon which the first end adaptor may be translated.

19. The apparatus of claim 18, wherein a height of the first end adaptor with respect to the one or more rails is adjustable.

20. The apparatus of claim 17, further comprising a second end adaptor, the second end adaptor sealably coupled to one of the one or more processing tubes and comprising:
a second loading port, the second loading port adapted to allow a second substrate to be loaded into the second reaction space;
a second gas input port, the second gas input port in gaseous communication with one of the one or more reactant gas manifolds and the second reaction space; and
a second gas exhaust port, the second gas exhaust port in gaseous communication with one of the one or more exhaust gas manifolds and the second reaction space.

21. A method for performing film deposition in a reactor, the method comprising the steps of:
placing a first substrate into a first reaction space while performing film deposition in a second reaction space, the second reaction space not in gaseous communication with the first reaction space;
introducing a first reactant gas flow into the first reaction space;
translating a heat source to a first position so as to direct energy into at least a portion of the first reaction space;
placing a second substrate into the second reaction space while performing film deposition in the first reaction space;
introducing a second reactant gas flow into the second reaction space; and
translating the heat source to a second position so as to direct energy into at least a portion of the second reaction space.

22. A product of manufacture, the product of manufacture comprising a film deposited in an apparatus, the apparatus comprising:
one or more processing tubes, the one or more processing tubes defining a first reaction space and a second reaction space, the second reaction space not in gaseous communication with the first reaction space;
a heat source, the heat source being translatable so as to direct energy into at least a portion of the first reaction space when the energy source is in a first position, and to direct energy into at least a portion of the second reaction space when the energy source is in a second position;
one or more reactant gas manifolds, the one or more reactant gas manifolds operative to introduce a first reactant gas flow into the first reaction space, and to introduce a second reactant gas flow into the second reaction space; and
one or more exhaust gas manifolds, the one or more exhaust gas manifolds operative to exhaust gases from the first reaction space and from the second reaction space.
